(19) United States
(12) Patent Application Publication
(10) Pub. No.: US 2005/0241586 A1
(43) Pub. Date: Nov. 3, 2005

(54) Vacuum vapor deposition apparatus

(75) Inventors: Chuan-De Huang, Tu-Cheng (TW); Wen-Jeng Huang, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/044,602

(22) Filed: Jan. 27, 2005

(30) Foreign Application Priority Data
Apr. 30, 2004 (TW) 93112194

(51) Int. Cl. C23C 16/00

(52) U.S. Cl. 118/730

(57) ABSTRACT

A vacuum vapor deposition apparatus includes a evacuable container (11), a support mechanism (30) disposed inside the evacuable container and including a support frame (32) for supporting substrates (344) on turnable support plates (34), a rotating mechanism (20) disposed outside the evacuable container and attached to the support mechanism, and at least one vapor source (40) disposed inside the evacuable container and opposite to the support plates, for producing a vapor of material to be deposited on the substrates. The support mechanism includes a turning mechanism (36), and a control unit for controlling operation of the turning mechanism. The turning mechanism is connected with the support plates. The support plates are turnable in the container via the turning mechanism and the control unit.

### BACKGROUND OF THE INVENTION

1. Field of the Invention

The present invention relates to vacuum vapor deposition apparatuses, and particularly to a vacuum vapor deposition apparatus for coating two sides of optical substrates.

2. Related Art

A typical vacuum vapor deposition apparatus for coating a plurality of optical substrates such as plastic lenses for spectacles (e.g. sunglasses) comprises an evacuable container, at least one vapor source in the container, and a rotatable support means in the container for holding the substrates.

This kind of vacuum vapor deposition apparatus is widely used for producing reflection-reducing coatings on plastic, glass, and other lenses. Ideally, as many articles as possible and as many surfaces as possible are coated in a same vacuum cycle, since the idle time between individual cycles is comparatively long.

To this end, the rotatable support means is located in an upper portion of the container, and has a plurality of mounting openings for holding the optical substrates therein in a uniform arrangement. When coating of first surfaces of the substrates is finished, the container is opened. The substrates are then either turned in the support means, or removed from the support means and repositioned in the support means. Then opposite second surfaces of the substrates can subsequently be coated.

This kind of mechanism is described as part of a vacuum deposition apparatus in P.R. China Patent No. 00212144.1 issued on Mar. 3, 2001. The vacuum deposition apparatus is intended for coating of both sides of a plurality of substrates, such as lenses. The vacuum deposition apparatus includes a container, a support frame provided with support plates, a vapor source, and a pump disposed outside the container. In operation, the substrates are attached to the support plates, respectively. The support plates are conducted in succession past the vapor source inside the container so that first sides of the substrates are coated in a first vacuum cycle. The support plates are then moved out of the container, and inverted. Subsequently the support plates are again conducted in succession past the vapor source inside the container so that second sides of the substrates are coated in a second vacuum cycle. The above-described process may be repeated for third and subsequent vacuum cycles, as required.

With this kind of vacuum deposition apparatus, the vacuum of each cycle of deposition is lost upon changing of the positions of the substrates, and the number of cycles of deposition needed is time-consuming. In addition, after changing of the positions of the substrates, the vacuum of the next cycle may be different from the vacuum of the previous cycle. If this happens, the coatings on the opposite sides of the substrates are likely to be different.

Therefore, a new vacuum vapor deposition apparatus that overcomes the above-described problems is desired.

### SUMMARY OF THE INVENTION

It is therefore an object of the present invention is to provide a vacuum vapor deposition apparatus for coating a plurality of optical substrates which readily performs coating of surfaces of the substrates in a same vacuum cycle.

Another object of the present invention is to provide a vacuum vapor deposition apparatus that has a relatively simple construction.

To achieve the above objects, a vacuum vapor deposition apparatus according to the present invention comprises a evacuable container, a support mechanism disposed inside the evacuable container and including a support frame for supporting substrates on turnable support plates, a rotating mechanism disposed outside the evacuable container and attached to the support mechanism, and at least one vapor source disposed inside the evacuable container and opposite to the support plates, for producing a vapor of material to be deposited on the substrates. The support mechanism further includes a turning mechanism and a control unit for controlling operation of the turning mechanism. The turning mechanism is connected with the support plates. The support plates are turnable in the container via the turning mechanism and the control unit.

A main advantage of the invention is that the support plates of the support mechanism can be turned. Accordingly, both sides of the substrates can be coated in a single vacuum cycle.

Other objects, advantages and novel features of the invention will become more apparent from the following detailed description when taken in conjunction with the accompanying drawings, in which:

### BRIEF DESCRIPTION OF THE DRAWINGS

FIG. 1 is an isometric view of a vacuum vapor deposition apparatus according to a preferred embodiment of the present invention, the vacuum vapor deposition apparatus comprising a support mechanism including a turning mechanism;

FIG. 2 is an enlarged, isometric view of the support mechanism including the turning mechanism of the vacuum vapor deposition apparatus of FIG. 1; and

FIG. 3 is a cross-sectional view taken along line III-III of FIG. 2.

### DETAILED DESCRIPTION OF THE INVENTION

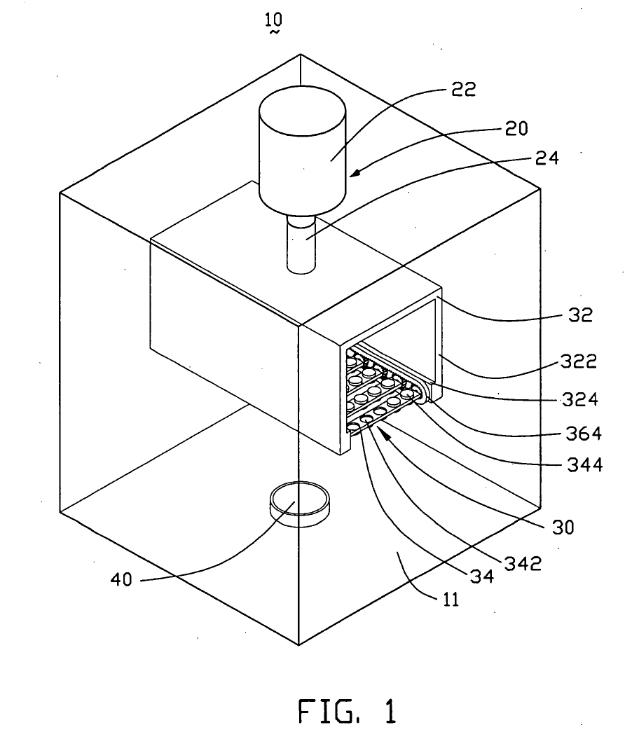

FIG. 1 shows a vacuum vapor deposition apparatus 10 according to the preferred embodiment of the present invention. The vacuum vapor deposition apparatus 10 is used to deposit a coating on a plurality of workpieces like optical substrates 344, which may for example be plastic lenses for spectacles. The vacuum vapor deposition apparatus 10 comprises a box-shaped, transparent container 11 evacuable by a vacuum pump (not shown), a rotating mechanism 20 installed outside of the container 11, a support mechanism 30 installed inside of the container 11, and at least one vapor source 40. The support mechanism 30 includes a generally box-shaped support frame 32, a plurality of support plates 34, and a turning mechanism 36. The rotating mechanism 20 and the turning mechanism 36 are controllable by a control unit (not shown) installed outside of the container 11.

The rotating mechanism 20 includes a main motor 22 and a rotating axle 24. The main motor 22 is mechanically connected with the support frame 32 of the support mechanism 30 via the rotating axle 24. The main motor 22 can thus drive the support mechanism 30 to rotate, so that all the substrates 344 attain a uniform coating on all surfaces thereof to be coated.

The support frame 32 is located in an upper chamber region of the container 11. The support frame 32 is generally quadrate, and has two opposite sidewalls 322. Each sidewall 322 has a longitudinal beam 324 perpendicularly extending from a bottom inner side thereof. Each longitudinal beam 324 defines a plurality of holes (not shown) arranged in a line and evenly spaced apart from each other.

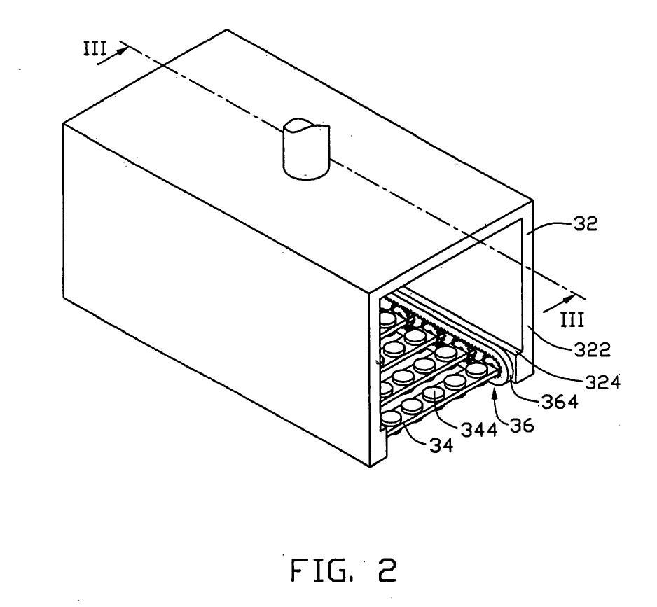

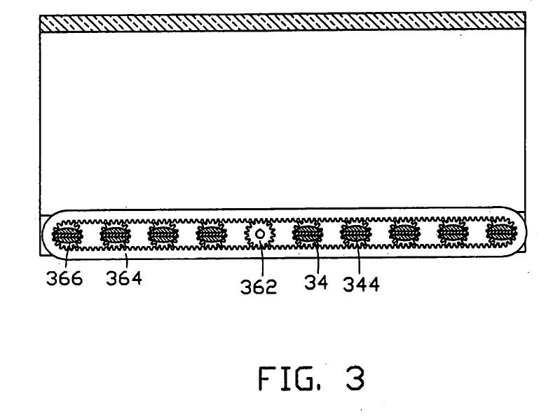

Referring also to FIG. 2 and FIG. 3, the support plates 34 are mounted horizontally and parallel to each other in the support frame 32. Each support plate 34 is mounted between a pair of corresponding holes of the longitudinal beam 324, so that the support plates 34 are evenly spaced apart from each other. The group of support plates 34 rotates about an axis of the rotating axle 24, and each support plate 34 is pivotable 360 degrees about a horizontal axis thereof. Each support plate 34 defines a plurality of openings 342, for securely mounting a plurality of substrates 344 therein. Generally, the substrates 344 are to be coated on both of opposite sides thereof.

The turning mechanism 36 comprises a turning motor (not shown), a turning gear 362, a drive belt 364, and a plurality of slave gears 366. The turning motor is connected with the turning gear 362 via a rotating axle (not shown) so as to drive the drive belt 364 and hence drive the rotation of the slave gears 366. The drive belt 364 engages with the turning gear 362 and the slave gears 366 to drive the slave gears 366 to rotate. The drive belt 364 can alternatively be a chain. An electrical wire of the turning motor can be extended to the outside of the container 11 via the support frame 32 and the rotating axle 24. The turning mechanism 36 is controllable by the control unit.

One end of each support plate 34 is connected with a corresponding rotating gear 366, and extends into the corresponding hole of the longitudinal beam 324 that abuts the drive belt 364. Said end of the support plate 34 can rotate in the hole. The other end of the support plate 34 extends into the corresponding hole of the other longitudinal beam 324 that is opposite from the drive belt 364, and can rotate in that hole.

The vapor source 40 is installed in a bottom of the container 11 directly under the support plates 34. The vapor source 40 comprises an electron beam gun, which produces an electron beam. For example, the electron beam can be produced by a tungsten cathode at a high negative potential.

When coating the substrates 344, the main motor 22 rotates the rotating axle 24, which drives the support frame 32 and the support plates 34 to rotate together so that first sides of the substrates 344 are coated. When the coating of the first sides of the substrates 344 is completed, the rotating speed of the support frame 32 is slowed down until the support frame 32 completely stops rotating. Then, the turning motor is turned on, and drives the turning gear 362 rotate. Because of the engagement between the turning gear 362 and the drive belt 364, the driving force of the turning gear 362 is transmitted to the slave gears 366 so that the slave gears 366 rotate. The support plates 34 rotate together with the slave gears 366 so that the substrates 344 are turned upside down 180 degrees. When the turning of the substrates 344 is completed, the turning motor is turned off. Then the main motor 22 is turned on again. The main motor 22 again drives the support frame 32 to rotate, so that opposite second sides of the substrates 344 are coated.

In alternative embodiments, the container 11 can be spherical or cylindrical. The support frame 32 can be hemispherical. Two or more turning motors and/or turning gears 362 can be employed according to need. In particular, opposite sides of the support frame 32 can each be provided with a turning motor and a turning gear 362, so that the support frame 32 is balanced and can be rotated by the rotating mechanism 20 smoothly. In such case, turning motors with lower power can be used, which reduces the overall size of the vacuum vapor deposition apparatus 10.

The main motor 22 and the turning motor are controlled by the control unit, which is provided with a plurality of buttons corresponding to internal controlling circuits. This enables an operator to manually operate and adjust the main motor 22 and the turning motor according to need. Further, the turning motor can be controlled by a remote control of the control unit.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

1. A vacuum vapor deposition apparatus for depositing material on workpieces, comprising:
an evacuable container;
a support mechanism inside the evacuable container, including a support frame having turnable support plates for supporting the workpieces thereon;
a rotating mechanism outside the evacuable container, and drivably attached to the support mechanism so that the support mechanism can rotate;
at least one vapor source inside the evacuable container opposite to the support plates, for producing a vapor of material to be deposited on the workpieces;
wherein the support mechanism further includes a turning mechanism and a control unit for controlling operation of the turning mechanism, the turning mechanism is connected with the support plates, the plurality of support plates are turnable in the container via the turning mechanism and the control unit.

2. The vacuum vapor deposition apparatus as claimed in claim 1, wherein the turning mechanism comprises a turning motor, a turning gear, a drive belt, and a plurality of slave gears, the turning motor is attached to the turning gear, the drive belt engages with the turning gear and the slave gears respectively, and the slave gears are respectively attached to the support plates.

3. The vacuum vapor deposition apparatus as claimed in claim 2, wherein the drive belt is a chain.

4. The vacuum vapor deposition apparatus as claimed in claim 1, wherein the rotating mechanism includes a rotating motor and a rotating axle, and the support mechanism is attached to the rotating axle and rotates about an axis of the rotating axle.

5. The vacuum vapor deposition apparatus as claimed in claim 4, wherein the support frame is generally quadrate, and includes two opposite sidewalls.

6. The vacuum vapor deposition apparatus as claimed in claim 5, wherein each sidewall defines a plurality of aligned, spaced-apart holes, the holes receiving distal ends of corresponding support plates.

7. The vacuum vapor deposition apparatus as claimed in claim 1, wherein each support plate defines a plurality of openings for securely mounting workpieces therein.

8. The vacuum vapor deposition apparatus as claimed in claim 1, wherein the container is box-shaped, spherical, or cylindrical.

9. The vacuum vapor deposition apparatus as claimed in claim 1, wherein the vapor source is an electron beam gun.

10. A vacuum vapor deposition apparatus, comprising:
an evacuable container;
an external vacuum pump for controllably evacuating the evacuable container;
at least one vapor source, disposed at a lower position inside the evacuable container, for producing a vapor of material to be deposited on the workpieces;
a support mechanism, disposed at an upper position inside the evacuable container, the support mechanism having turnable support plates for supporting the workpieces thereon;
an external rotating mechanism mechanically coupled to the support mechanism by an axle, for controllably rotating the support mechanism;
a turning mechanism mechanically coupled to the support plates, for controllably turning the support plates; and
a control unit operatively coupled to the vacuum pump, the rotating mechanism and the support mechanism.

11. The vacuum vapor deposition apparatus as claimed in claim 10, wherein the turning mechanism comprises a turning motor, a turning gear, a drive belt, and a plurality of slave gears, the turning motor is attached to the turning gear, the drive belt engages with the turning gear and the slave gears respectively, and the slave gears are respectively attached to the support plates.

12. The vacuum vapor deposition apparatus as claimed in claim 11, wherein the drive belt is a chain.

13. The vacuum vapor deposition apparatus as claimed in claim 10, wherein the rotating mechanism includes a rotating motor and a rotating axle, and the support mechanism is attached to the rotating axle and can rotate with the rotating axle.

14. The vacuum vapor deposition apparatus as claimed in claim 10, wherein the support mechanism includes a support frame.

15. The vacuum vapor deposition apparatus as claimed in claim 14, wherein the support frame is generally quadrate and includes two opposite sidewalls.

16. The vacuum vapor deposition apparatus as claimed in claim 15, wherein each sidewall defines a plurality of aligned, spaced-apart holes, the holes receiving distal ends of corresponding support plates.

17. The vacuum vapor deposition apparatus as claimed in claim 10, wherein each support plate defines a plurality of openings for securely mounting workpieces therein.

18. The vacuum vapor deposition apparatus as claimed in claim 10, wherein the container is box-shaped, spherical, or cylindrical.

19. The vacuum vapor deposition apparatus as claimed in claim 10, wherein the vapor source is an electron beam gun.

20. A vacuum vapor deposition apparatus, comprising:
a container used to maintain a vacuum condition therein;
at least one vapor source disposed in said container to provide depositable material therefrom;
a support mechanism used to rotatably support at least one workpiece in said container and have one side of said at least one workpiece supportively facing said at least one vapor source so as to allow said depositable material depositable on said one side in said vacuum condition and allow said at least one workpiece rotatable relative to said support mechanism; and
a turning mechanism attached to said support mechanism to perform rotation of said at least one workpiece so as to have another side, other than said one side, of said at least one workpiece facing said at least one vapor source to allow said depositable material depositable on said another side.
